(19) United States
(12) Patent Application Publication
(10) Pub. No.: US 2008/0180136 A1
(43) Pub. Date: Jul. 31, 2008

(54) Pre-charge sample-and-hold circuit

(76) Inventors: Jieh-Tsorng Wu, Hsinchu City (TW); Zwei-Mei Lee, Longtan Township (TW); Cheng-Yeh Wang, Jhubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/715,476

(22) Filed: Mar. 8, 2007

(30) Foreign Application Priority Data
Jan. 26, 2007 (TW) 96102952

(51) Int. Cl. G11C 27/02

(52) U.S. Cl. 327/94

(57) ABSTRACT

A precharge sample-and-hold circuit is formed by coupling a buffer with an input port and making use of a switch to conduct the circuit between the buffer and a total load capacitor for precharging according the state of a sample-and-hold circuit. When the sample-and-hold circuit is in the sample mode, it precharges the total load capacitor. When the sample-and-hold circuit is in the hold mode, the influence to the sampled signal is further reduced due to the precharging. The requirements of swing rate, output voltage swing, gain-bandwidth product for the opamps can therefore be reduced, hence being applicable to the realization of the design of advanced fabrication technologies of low supply voltages.

### BACKGROUND OF THE INVENTION

1. Field of the Invention

The present invention relates to a sample-and-hold circuit and, more particularly, to a sample-and-hold circuit that can be charged in advance.

2. Description of Related Art

Most physical signals produced in everyday life exist in analog form. Usually, analog signals are converted to digital form for further processing because digital signals are less affected by interference and their operations are more economic. High-resolution high-speed Nyquist-rate analog-to-digital converters (ADCs) have been predominantly realized using the pipeline architecture. High-gain opamps with linear feedback are often used to ensure the linearity of sample-and-hole amplifiers and pipeline stages. In recent years, the performance of digital processing circuits have been greatly enhanced owing to the progress of the semiconductor fabrication processes. Not only the operation clock constantly increases, the circuit area also continually shrinks with the fabrication process, therefore making the application of digital signal processing wider day by day.

In U.S. Pat. No. 6,992,509, yet another sampling switched-capacitor network is adopted. The two sampling switched-capacitor networks sample and hold alternately. In each hold mode, the swing rate and settling time requirements for the opamp can be reduced because the level of the output signal held in the previous mode is close to the desired level to be settled. This method, however, does not apply to high-frequency input signals. When the input frequency approaches the Nyquist rate, the proposed advantage no longer exists. At this time, this method requires a larger swing rate for the opamp than the conventional method without precharging, in which the output is reset to the common-mode level using the sample mode time.

Accordingly, the present invention aims to propose a precharge sample-and-hold circuit to solve the above problems in the prior art.

### SUMMARY OF THE INVENTION

An object of the present invention is to provide a precharge sample-and-hold circuit, which uses a precharging path to precharge the output load to reduce the influence of the load to the sampled signal.

Another object of the present invention is to provide a precharge sample-and-hold circuit, which makes use of the result of precharging the output load to reduce the swing rate, output voltage swing, and gain-bandwidth product requirements for the opamps.

Yet another object of the present invention is to provide a precharge sample-and-hold circuit, which achieves precharging via a precharging path to apply to time-interlaced systems.

To achieve the above objects, the present invention provides a precharge sample-and-hold circuit, which comprises an input port for inputting a voltage signal, a buffer, a sample-and-hold circuit, and a switch. The buffer is connected to the input port and the switch to form a precharging path. When the sample-and-hold circuit is in the sample mode, the switch is turned on to conduct the circuit between the buffer and a total load capacitor to precharge the total load capacitor, and to precharge a coupling capacitor by means of DC coupling. In this sample-and-hold circuit, a sampling capacitor and a parasitic capacitor are also precharged via a first switch connected to the input port. When the sample-and-hold circuit is in the hold mode, a second switch connected to an output port and a sampling capacitor is turned on to conduct the circuit between the output port and the sampling capacitor to hold the signal at the desired signal level. Therefore, in the hold mode, the swing rate, output voltage swing, gain-bandwidth product requirements for the opamps in the circuit can be furthermore reduced. Moreover, the influence of the output load to the sampled signal is lowered to be more suitable to applications in time-interlaced systems.

### BRIEF DESCRIPTION OF THE DRAWINGS

The various objects and advantages of the present invention will be more readily understood from the following detailed description when read in conjunction with the appended drawing, in which:

FIG. 1 is a circuit diagram of the precharge sample-and-hold circuit of the present invention;

FIG. 2 is a diagram showing the relation between I/O signals and sampling clock and time of the precharge sample-and-hold circuit of the present invention;

FIG. 3 is a circuit diagram of a single terminal output configuration of the precharge sample-and-hold circuit of the present invention;

FIG. 4 is a time sequence diagram of a single terminal output configuration of the precharge sample-and-hold circuit of the present invention; and

FIG. 5 is a circuit diagram of the precharge sample-and-hold circuit of the present invention applied to the input sampling network of a time-interlaced analog-to-digital converter (ADC).

### DETAILED DESCRIPTION OF THE PREFERRED EMBODIMENTS

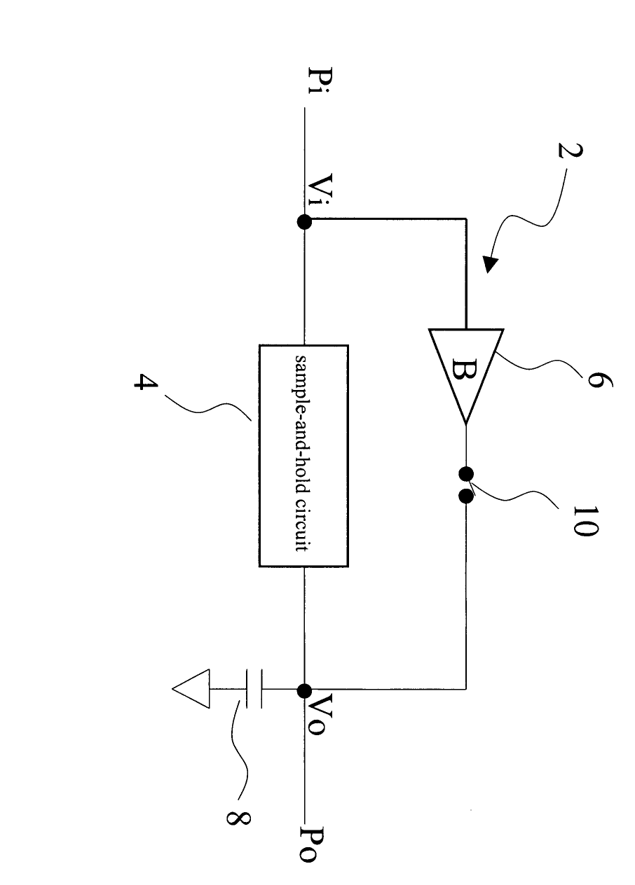

As shown in FIG. 1, a precharge sample-and-hold circuit comprises a buffer 6, a switch 10, and a sample-and-hold circuit 4. The buffer 6 and the switch 10 together form a precharging path. When the sample-and-hold circuit 4 is in the sample mode, a total load capacitor 8 of an output port Po is precharged. When the sample-and-hold circuit 4 is in the hold mode, the switch 10 is opened to cut off the precharging path so as to restore to the normal hold action of the sample-and-hold circuit 4.

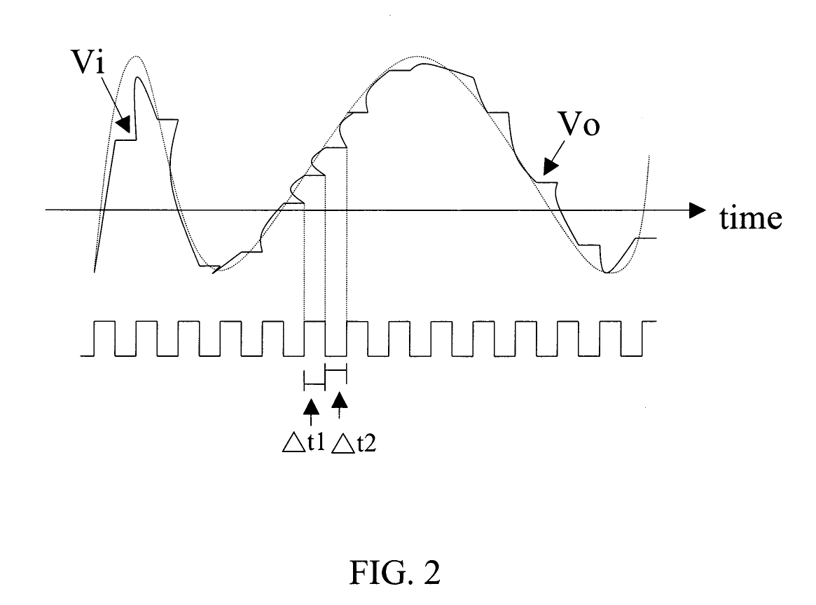

As shown in FIG. 2, in the sample mode (e.g., Δt1), the output signal Vo is charged via the path from the buffer 6 to the switch 10. Therefore, the output signal Vo follows the input signal Vi to change. In the hold mode (Δt2), the output signal Vo only needs a small swing to reach the final stable value.

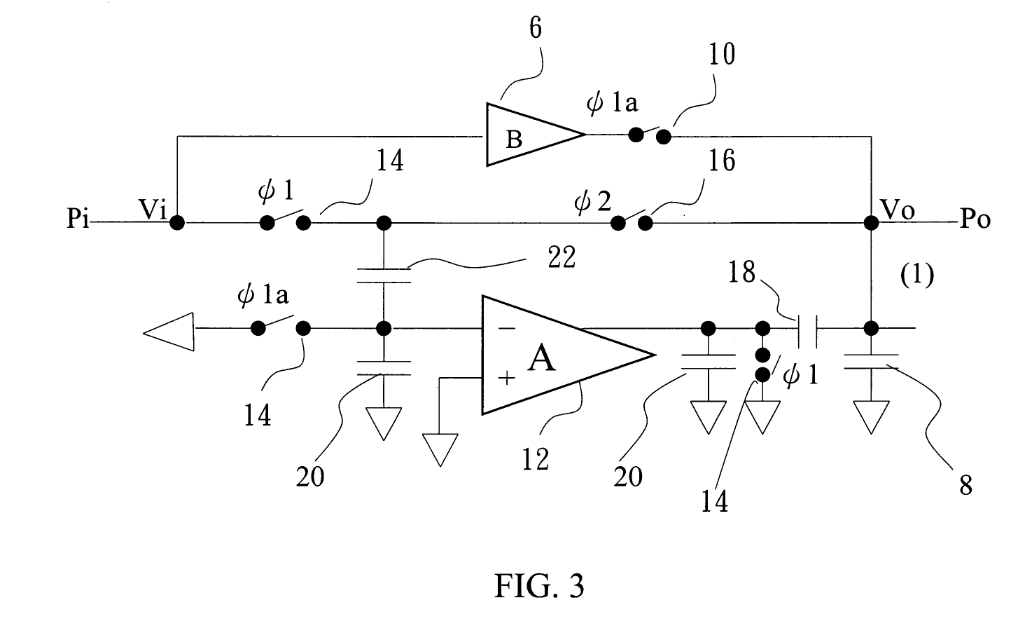

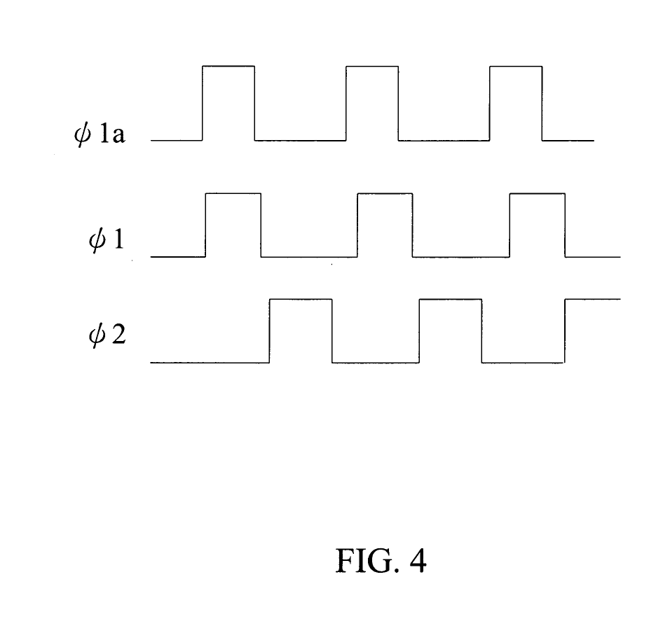

As shown in FIGS. 3 and 4, the sample-and-hold circuit 4 comprises a first switch 14, a second switch 16, an opamp 12, and a parasitic capacitor 20 and a coupling capacitor 18 connected to the opamp12. The first switch 14 is coupled with an input port Pi, and is turned on to conduct the circuit between the input port Pi and a sampling capacitor 22 according to the sample phase state. The second switch 16 is connected to the output port Po and the sampling capacitor 22, and is turned on to conduct the output port Po and the sampling capacitor 22 to hold the signal at the desired signal level. The opamp 12 is connected to the sampling capacitor 22, and is used to send out the voltage signal stored on the sampling capacitor 22. When the sample-and-hold circuit 4 is in the sample mode (i.e., φ₁ₐ=1, φ₁=1), the switch 10 and the first switch 14 are on, and the input signal Vi charges the sampling capacitor 22. The input signal Vi also charges the coupling capacitor 18 and the total load capacitor 8 on the output port Po(1) via the buffer 6 and the switch 10 that is turned on. Besides, the parasitic capacitor 20 of the output port Po of the opamp 12 is also precharged by means of DC coupling of the coupling capacitor 18. When the sample-and-hold circuit 4 changes to the hold mode (i.e., Φ₁ₐ=0, Φ₁=0 and Φ₂=1), the switch 10 and the first switch 14 will be off. Meanwhile, the second switch 16 is turned on, and the output signal Vo will settle to the signal level sampled by the sampling capacitor 22. Because in the sample mode, the output signal Vo has been precharged via the path from the buffer 6 to the switch 10, the output signal Vo can quickly swing to the signal level sampled by the sampling capacitor 22 when changing to the hold mode. Therefore, the swing rate requirement for the opamp 12 can be greatly reduced. Moreover, because the output voltage swing is also reduced due to the precharging, a shorter swing time is required to swing to the signal level sampled by the sampling capacitor 22, hence having a longer settling time under a constant clock period. Therefore, the gain-bandwidth product requirement for the opamp 12 can be relatively mitigated. The present invention can also be extended to apply to a full-differential configuration of sample-and-hold circuit. The procedures are the same as those of the above single-end output configuration of sample-and-hold circuit and thus won't be further described.

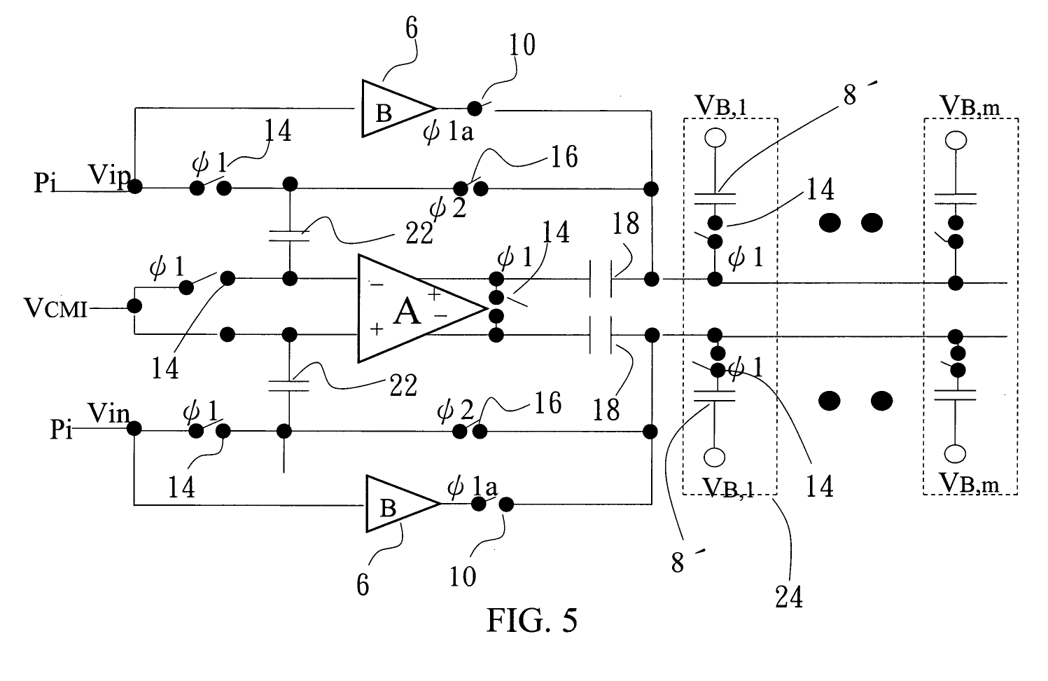

As shown in FIG. 5, a precharge sample-and-hold circuit of the present invention is applied to the input sampling network of a time-interlaced ADC. The precharge sample-and-hold circuit comprises a buffer 6, a switch 10, and a sample-and-hold circuit 4. The buffer 6 and the switch 10 together form a precharging path. An ADC input sampling network 24 is connected to the precharge sample-and-hold circuit via a circuit. When the circuit is in the sample mode (i.e., Φ₁ₐ=1, Φ₁=1), the input signal Vi charges the sampling capacitor 22 and simultaneously precharges a total load capacitor 8′ of the first converter channel. In this period, the output port Po of the opamp 12 will be equalized by the first switch 14. Therefore, a coupling capacitor 18 is added. When changing to the hold mode, the output port Po of the opamp 12 will settle to its final value without swing in a very short period of time due to the precharging. The combination of the added coupling capacitor 18 and the precharging reduces the opamp's dc gain and output voltage swing requirements so that higher speed can be achieved.

To sum up, the present invention provides a precharge sample-and-hold circuit. Owing to precharging, the swing rate, output voltage swing, and gain-bandwidth product requirements for the opamp of the circuit itself can be reduced. Therefore, the present invention applies to advanced fabrication technologies of low supply voltages. Moreover, it is only necessary to add a simple buffer and switch network to avoid the influence of output load mismatch to the output response of the sample-and-hold circuit. The present invention is thus suitable to applications in the architecture design of time-interlaced systems.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A precharge sample-and-hold circuit comprising:
an input port capable of inputting a voltage signal;
a sample-and-hold circuit connected to said input port and used for sending said voltage signal to an output port;
a buffer coupled with said input port and used for receiving said voltage signal to precharge a passive component; and
a switch connected to said buffer and said output port and used to conduct the circuit between said buffer and said passive component according to the state of said sample-and-hold circuit.

2. The precharge sample-and-hold circuit as claimed in claim 1, wherein said passive component is precharged when said sample-and-hold is in the sample mode, and said switch is opened to close the precharging path to restore to the normal holding action of said sample-and-hold circuit when said sample-and-hold is in the hold mode.

3. The precharge sample-and-hold circuit as claimed in claim 1, wherein said passive component is a total load capacitor.

4. The precharge sample-and-hold circuit as claimed in claim 1, wherein said sample-and-hold further comprises:
a first switch coupled with said input port and used to conduct said input port and a sampling capacitor for precharging according to the sample phase state;
a second switch connected to said output port and said sampling capacitor and used to conduct said output port and said sampling capacitor to hold a signal at the desired signal level;
an opamp connected to said sampling capacitor and used to send out a voltage signal stored on said sampling capacitor;
a coupling capacitor coupled with an output port of said opamp; and
at least a parasitic capacitor connected to said opamp.

5. The precharge sample-and-hold circuit as claimed in claim 4, wherein said coupling capacitor receives said input voltage signal via said buffer for precharging.

6. The precharge sample-and-hold circuit as claimed in claim 4, wherein said coupling capacitor is precharged by means of DC coupling of said coupling capacitor.

7. The precharge sample-and-hold circuit as claimed in claim 1, wherein said switch controls the sampling of said input signal and the holding of the sampled signal.

8. A precharge sample-and-hold circuit comprising:
an input port capable of inputting a voltage signal;
a sample-and-hold circuit connected to said input port and used for sending said voltage signal to an output port;
a buffer coupled with said input port and used for receiving said voltage signal to precharge at least a passive component;
a switch connected to said buffer and said output port and used to control the circuit between said buffer and said passive component; and
an ADC input sampling network connected to said sample-and-hold circuit via a circuit, said ADC input sampling network conducting the circuit between said buffer and said passive component according to the state of said sample-and-hold circuit to transmit a voltage signal at said input port to an output network connected to said passive component to be sent out.

9. The precharge sample-and-hold circuit as claimed in claim 8, wherein said ADC input sampling network is one or more ADC channels.

10. The precharge sample-and-hold circuit as claimed in claim 8, wherein the voltage signal of said ADC input sampling network is of a constant bias level.
